(19) United States
(12) Patent Application Publication
(10) Pub. No.: US 2011/0062450 A1
(43) Pub. Date: Mar. 17, 2011

(54) Silicon carbide semiconductor device

(75) Inventors: Peter Michael Gammon, Hampshire (GB); Phil Mawby, Warwick (GB); Amador Pérez-Tomás, Barcelona (ES)

(73) Assignee: The University of Warwick

(21) Appl. No.: 12/586,018

(22) Filed: Sep. 15, 2009

(51) Int. Cl. H01L 29/24; H01L 21/04

(52) U.S. Cl. 257/77; 438/509; 257/183; 257/E21.054; 257/E29.104

(57) ABSTRACT

A silicon carbide semiconductor device comprising a region of germanium and a region of crystalline or polycrystalline silicon carbide. The germanium region and the silicon carbide region are configured to form a germanium/silicon carbide heterojunction.

### FIELD OF THE INVENTION

The present invention relates to a silicon carbide semiconductor device, particularly, but not exclusively, for use in power electronics.

### BACKGROUND

Silicon carbide (SiC) is expected to be an excellent material for future generations of power electronic devices. SiC power diodes are widely used, taking advantage of the material's superior reverse breakdown voltage, lower on-resistance, and faster switching speed when compared to silicon (Si). However, while steps toward a SiC metal-oxide semiconductor field-effect transistor (MOSFET) continue to be made, the development of a commercial device is still being hindered by the material's high concentration of traps at the SiC/SiO₂ interface, which reduces the material's low channel mobility.

To overcome this, a heterojunction solution has been proposed, whereby silicon forms an epitaxial layer upon a SiC substrate. This combines the advantages of the two materials, namely high carrier mobility and the potential for a carbon-free oxide on the silicon, while retaining the reverse blocking capabilities of the SiC. Reference is made to “Characterization and modeling of n-n Si/SiC heterojunction diodes”, A. Pérez-Tomás, M. R. Jennings, M. Davis, J. A. Covington, P. A. Mawby, V. Shah and T. Grasby, Journal of Applied Physics, volume 102, page 014505 (2007) which is incorporated herein by reference.

Reference is also made to U.S. Pat. No. 7,282,739 which describes a silicon carbide semiconductor device having a silicon carbide semiconductor substrate and a heterojunction region made of silicon, amorphous silicon or polysilicon forming a heterojunction with the silicon carbide substrate.

The present invention seeks to improve the performance of a silicon carbide semiconductor device.

### SUMMARY OF CERTAIN EMBODIMENTS OF THE INVENTION

According to certain embodiments of the present invention there is provided a silicon carbide semiconductor device. The silicon carbide semiconductor device comprises a region of germanium and a region of crystalline or polycrystalline silicon carbide. The germanium region and the silicon carbide region are configured to form a germanium/silicon carbide heterojunction

Thus, despite a seemingly apparent incompatibility between germanium and silicon carbide due to severe lattice mismatch, germanium can in fact form a heterojunction with silicon carbide. For the same doping density, germanium has a higher mobility than silicon and so silicon carbide semiconductor devices which use germanium instead of silicon can be faster. For example, electron mobility in germanium at room temperature is about 3900 cm²V⁻¹s⁻¹, whereas for silicon, electron mobility is about 1450 cm²V⁻¹s⁻¹. The difference is even greater for hole mobility. Hole mobility in germanium at room temperature is about 1800 cm²V⁻¹s⁻¹, whereas for silicon, hole mobility is about 505 cm²V⁻¹s⁻¹. Germanium may also form a smoother interface on silicon carbide and, thus, reduce interface scattering.

The crystalline or polycrystalline silicon carbide region may comprise an epitaxial region of silicon carbide overlying a silicon carbide substrate. The silicon carbide region comprises a layer having a thickness of at least 1 μm.

The silicon carbide region may be doped, for example n-type or p-type.

The germanium region may comprise crystalline germanium, for example, deposited by wafer bonding. The germanium region may comprise polycrystalline germanium. The germanium region may comprise amorphous germanium. The germanium region may comprise an epitaxial layer of germanium. The germanium region may comprise a layer having a thickness of at least one monolayer. The germanium region may comprise a layer having a thickness of at least 10 nm. The germanium region may comprise a layer having a thickness of at least 100 nm. The germanium layer may have a thickness of up to about 1000 nm. The germanium region may be a thin-film layer. The germanium region may be bulk germanium.

The device may further comprise first and second electrodes, the first and second electrodes, the silicon carbide region and germanium region configured such that, in response to a bias applied between the first and second electrode, a current flows through the germanium/silicon carbide heterojunction.

The device may be a rectifier, for example a power rectifier. The device may be a transistor, for example a power transistor. The device may be a vertical-channel metal oxide semiconductor field effect transistor.

According to some embodiments of the present invention there is provided a silicon carbide semiconductor device comprising a crystalline substrate of silicon carbide, a layer of epitaxial silicon carbide overlying the silicon carbide substrate, a layer of crystalline or polycrystalline germanium overlying the epitaxial silicon carbide layer, wherein a heterojunction is formed at an interface between the germanium layer and the epitaxial silicon carbide layer.

The epitaxial silicon carbide layer may be n-type or p-type. The germanium layer may be n-type or p-type. The germanium layer may be intrinsic or doped to a concentration of up to about 1×10¹⁵ cm⁻³. The germanium layer may be doped to a concentration of up to about 5×10¹⁸ cm⁻³.

According to certain embodiments of the present invention there is provided a method comprising providing a region of crystalline or polycrystalline silicon carbide and providing a region of germanium, the germanium region and the silicon carbide region configured to form a germanium/silicon carbide heterojunction.

Providing the germanium region may comprise depositing a layer of germanium on the silicon carbide region. The germanium layer may be deposited at a temperature of between about 200° C. and 600° C. The germanium layer may be grown at a temperature of between about 400° C. and 600° C., for example at around 500° C. The germanium layer may have a thickness of at least one monolayer. The germanium layer may have a thickness of between about 100 nm and 1000 nm.

### BRIEF DESCRIPTION OF THE DRAWINGS

Certain embodiments of the present invention will now be described, by way of example, with reference to the accompanying drawings in which:

FIGS. 1A-1D illustrate different stages during fabrication of n-n Ge/SiC heterojunction diodes having Ge layers which have different thicknesses and compositions and which are deposited at different temperatures;

FIG. 2 is a schematic of an arrangement used to measure n-n Ge/SiC heterojunction;

FIG. 3 show x-ray diffraction analysis scans for different layers of Ge deposited on 4H—SiC having different thicknesses and compositions and deposited at different temperatures and an energy dispersive x-ray plot for a layer of highly-doped Ge deposited on 4H—SiC at 300° C.;

FIGS. 4A-D are atomic force microscope (AFM) micrographs for different layers of Ge deposited on 4H—SiC having different thicknesses and compositions and deposited at different temperatures;

FIG. 5 are semilog current—voltage plots and capacitance—voltage plots for diodes having 200 μm-diameter top contacts before annealing;

FIG. 6 is a sectional view of a Schottky Barrier diode;

FIG. 7 is a plan view of the diode shown in FIG. 6;

FIG. 8 is band diagram for a n-type germanium/n-type silicon carbide heterojunction;

FIGS. 9A-9K illustrate different stages during fabrication of the Schottky barrier diode shown in FIG. 6;

FIG. 10 is a sectional view of a junction bipolar Schottky diode;

FIG. 11 is a sectional view of an alternative junction bipolar Schottky diode;

FIG. 12 illustrates a stage during fabrication of the junction bipolar Schottky diode shown in FIG. 10 and the alternative junction bipolar Schottky diode shown in FIG. 11;

FIG. 13 illustrates a stage during fabrication of alternative junction bipolar Schottky diode shown in FIG. 11;

FIG. 14 is a sectional view of a positive-intrinsic-negative diode;

FIG. 15 is a sectional view of an alternative positive-intrinsic-negative diode;

FIGS. 16A & 16B illustrate stages during fabrication of the positive-intrinsic-negative diode shown in FIG. 14 and the alternative positive-intrinsic-negative diode shown in FIG. 15;

FIG. 17 illustrate a stage during fabrication of the alternative positive-intrinsic-negative diode shown in FIG. 15;

FIG. 18 is a sectional view of a metal-oxide-semiconductor field effect transistor (MOSFET);

FIG. 19 is band diagram for a p-type germanium/n-type silicon carbide heterojunction; and

FIG. 20A-20P illustrate different stages during fabrication of the MOSFET shown in FIG. 18.

### DETAILED DESCRIPTION OF CERTAIN EMBODIMENTS

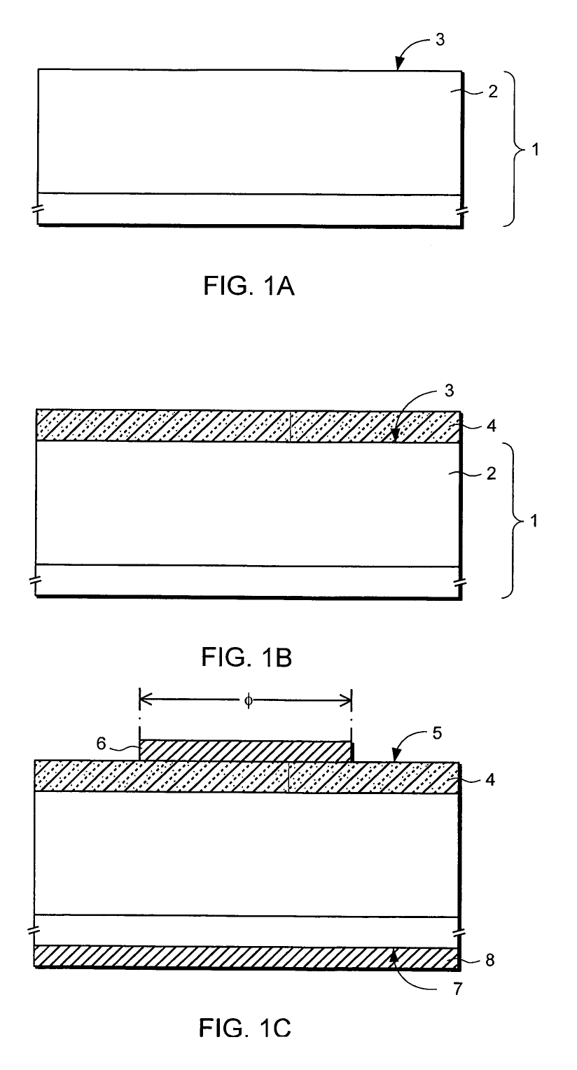

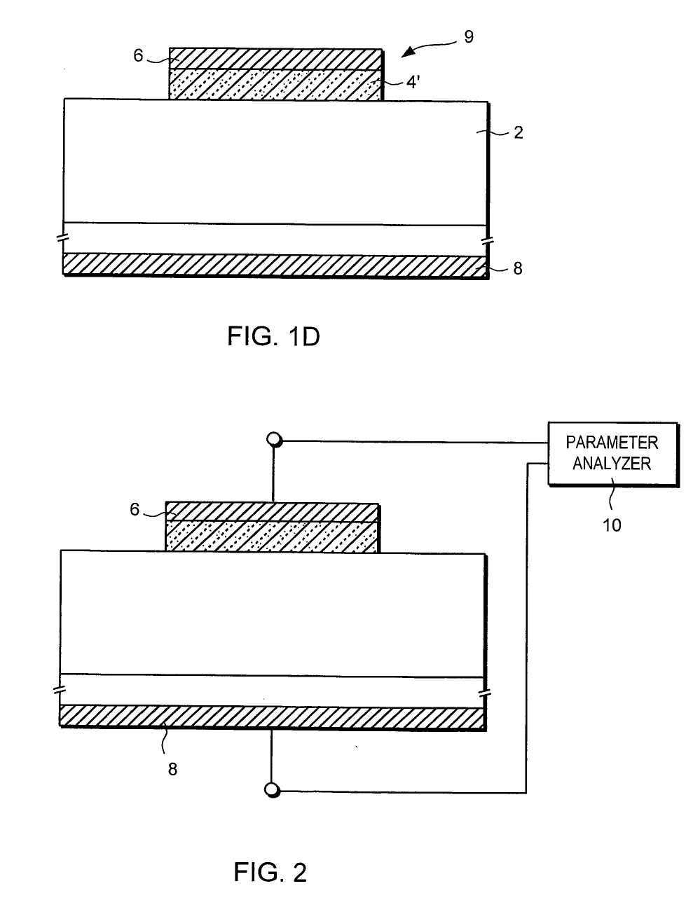

Referring to FIGS. 1A-1D, a method of fabricating a set of test devices according to certain embodiments of the present invention will now be described.

Referring in particular to FIG. 1A, an n-type (0001) Si face, 4° off axis, 4H-silicon carbide (SiC) wafer 1 is provided having a 10 μm, lightly n-type doped (1.4×10¹⁵ cm⁻³) epitaxial SiC layer 2 having an upper surface 3. A suitable wafer can be obtained from Cree Inc.

Prior to deposition, the wafer 1 is cleaned using a standard Radio Corporation of America-2 (RCA2) clean (H₂O:HCHl₂O₂) (not shown) followed by a hydrofluoric acid dip (not shown) to remove an oxide (not shown) formed during the RCA2 process.

The wafer 1 is loaded into an Oxford Instruments V100S molecular beam epitaxy (MBE) system (not shown). The wafer 1 is given a high-temperature bake within the MBE system to desorb any native oxide (not shown) and any other contaminants (not shown).

Referring in particular to FIG. 1B, devices are prepared in which germanium (Ge) 4 is deposited on the surface 3 of the wafer 1 under different conditions. Two devices have a single layer 4 of highly-doped, n-type Ge grown at different temperatures. Two devices have a pair of layers 4 consisting of an intrinsic layer of Ge and a highly-doped capping layer of n-type Ge.

In a first device, the layer 4 is a 100 nm-thick layer of highly-doped, n-type Ge, deposited at a rate of 0.1 Ås⁻¹ and at a temperature of 300° C. The layer 4 is doped with antimony (Sb) having a concentration of N_{D,Ge}=5×10¹⁹ cm⁻³. In a second device, the layer 4 has the same thickness and composition as the corresponding layer in the first device, but is deposited at temperature of 500° C.

In a third device, a 1 μm-thick layer of intrinsic germanium is deposited at a rate of 0.1 Ås⁻¹ and at a temperature of 300° C., and is capped with a layer of highly-doped, n-type germanium. In a fourth device, the intrinsic layer has the same thickness and composition as the corresponding layer in the third device, but is deposited at temperature of 500° C.

Referring to FIG. 1C, for each of the four devices, a 400 nm-thick layer of nickel (Ni) is sputtered onto the upper surface 5 of the Ge layer(s) 4 and patterned using a lift-off process to create a set of disc-shaped contacts 6 having diameters, 4), of 200 and 400 μm. Only one contact 6 is shown for clarity. A layer of Ni is also sputtered onto the back SiC surface 7 to form a back contact 8.

Referring to FIG. 1D, the contact 6 is used as an etch mask. The devices are etched down to the SiC layer 2 to form a patterned Ge layer 4′ and, thus, a mesa diode structure 9. The devices are heated at 450° C. in nitrogen ambient conditions for 5 minutes to anneal contacts 6, 8.

Referring to FIG. 2, the electrical properties of each device is characterised using a parameter analyzer 10 connected between the contacts 6, 8.

The crystallinity, and hence the conducting properties, of the Ge layers is investigated using x-ray diffraction (XRD) analysis. As will be explained in more detail hereinafter, there an increase by a factor of 500 in the resistivity of Ge from its crystalline to amorphous state.

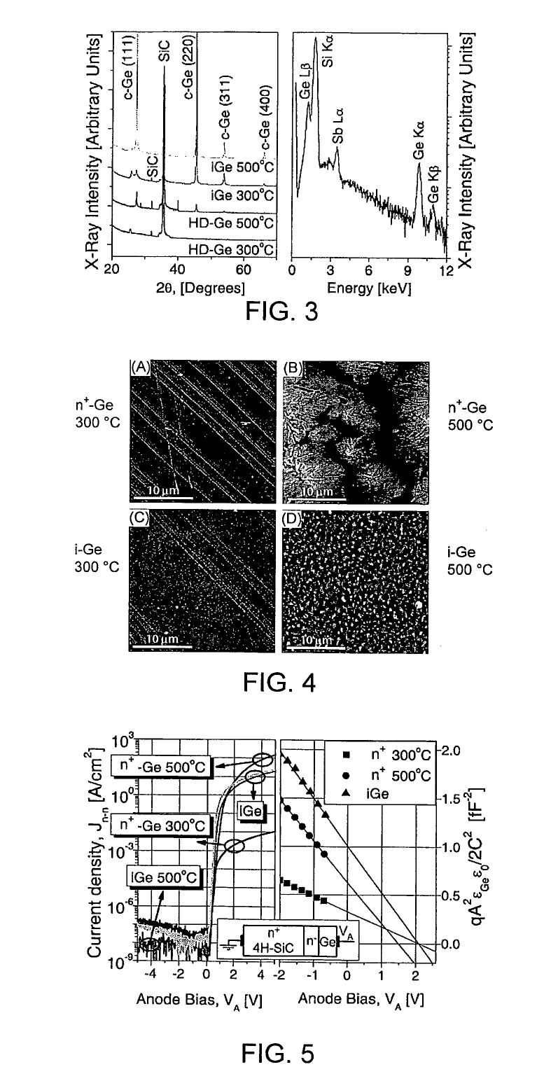

Referring to FIG. 3, cubic-Ge spikes are apparent from the θ-2θ scans. Also evident is the n-type 4H—SiC substrate for all the deposition conditions. Four main Ge peaks are evident for the devices comprising highly-doped Ge and intrinsic Ge deposited at 500° C., indicating that the Ge formed by the MBE process is polycrystalline.

The device having a highly-doped Ge layer grown at 300° C. displays an absence of Ge spikes suggesting that there is no crystalline Ge in this layer. To test for amorphous Ge in this device, energy dispersive x-ray (EDX) analysis is carried out. This technique is not reliant upon the material under scrutiny being crystalline for identification, unlike the XRD analysis. FIG. 3 shows that distinct Ge peaks are found along with peaks of the dopant element, antimony. Silicon is also highly visible. Carbon is, however, outside the range of this particular scan.

To form power devices, such as a MOSFET using a Ge/SiC heterojunction structure, the Ge layer should be smooth to minimize channel scattering after oxide growth. Hence, atomic force microscopy (AFM) analysis is used to study the quality of the surface 5 (FIG. 1C).

AFM scans taken prior to Ge deposition show smooth surfaces, although there is some evidence of step bunching having occurred during the SiC epitaxy growth. The root mean square (rms) roughness of the wafer 1 (FIG. 1A) is 1.5 nm.

FIGS. 4A-4D show contrasting surface roughnesses that appear over a 25 μm square area of the Ge layer in each device. The low-temperature depositions shown in FIGS. 4A and 4C reveal arms roughness of 4 and 3 nm, respectively, with the highly-doped Ge surface showing no evidence of crystalline Ge, confirming again its amorphous nature. Referring in particular to FIGS. 4B and 4D, both of the devices in which Ge is grown at 500° C. appear polycrystalline in nature. As shown in FIG. 4B, these crystals are distinct in the 100 nm layer of highly-doped Ge, with a rms roughness of 55 nm. It can be seen from the micrograph of this device that Ge has formed distinct crystalline clusters, with the SiC surface evident between them. As shown in FIG. 4D, the device in which a layer of intrinsic Ge is grown at 500° C. has an rms roughness of 45 nm, and the crystal grains are much smaller. Clusters such as these occur when atoms deposited on a surface seek an atomic site that minimizes the total energy of the system. Dangling (i.e. unattached) bonds add energy, and so atoms will begin to cluster together on a flat surface to minimize the number of unattached bonds. If this continues to occur two-dimensionally, then these are known as islands. The greater the deposition temperature, the more energy each atom will have to find a nucleation site, and hence, fewer larger islands are formed, as shown in FIG. 4B. High temperatures also allow atoms already deposited to migrate to a higher layer, and hence the islands start to form vertically from the substrate, known as a cluster. A possible remedy is to use a surface active agent (a “surfactant”) to aid a smooth heterolayer growth by introducing Group V atoms onto the surface. For example, it may be possible to use antimony (Sb) to change the growth mechanism within Ge layers from Stranski-Krastanov (islanding) growth to layer-by-layer growth.

Referring to FIG. 5, typical current-voltage (I-V) curves for the Ge/SiC n-n heterojunction devices are shown from which ideality factors and resistivity values can be extracted for each Ge layer.

All the diodes display a very low turn-on voltage, with the devices starting to turn on around 0.3 V. The device having a layer of intrinsic Ge grown at 500° C. produces a response with the lowest reverse leakage current of 9.1×10⁻⁹ A/cm² at −10 V and an ideality factor of 1.08. The diode having a layer of intrinsic Ge grown at 300° C. produces a similar ideality factor of 1.12 and a reverse leakage current of 4.5×10⁻⁷ A/cm². Such low ideality factors indicate that current transport is dominated by thermionic emission and not by recombination, thus showing that the electrical quality of the Ge/SiC junctions is good. This is supported by the low reverse leakage current. Both diodes having a layer of intrinsic Ge are fairly resistive since the intrinsic layers are estimated to make up about 70% and 62% of the total device resistance for the devices in which the Ge layer is grown at 300° C. and at 500° C. respectively. The device comprising a layer of highly-doped Ge grown at 300° C. is extremely resistive, which can be attributed to the amorphous layer having a significantly reduced electron mobility. However, with an ideality factor of 1.12 it is another high quality interface.

The device comprising a layer of highly-doped Ge grown at 500° C., meanwhile, displays a relatively low resistance but an ideality factor of 2.23. The polycrystalline highly-doped Ge layer in this device is estimated to be responsible for 10% of the total device resistivity. The poor interface quality of this device could be explained by the discontinuous surface morphology displayed in FIG. 4B. This patch contact suggests that Ni is directly in contact with the SiC, thus reducing the resistance at high voltages. It also explains the poor turn-on characteristic as current is able to travel through paths of varying resistance. It can be concluded from these results that all the diodes display a very low turn-on voltage, but the intrinsic Ge layers form better quality junctions with SiC than the highly-doped Ge layers. However, when deciding the appropriate deposition temperature, a trade-off appears to exist between the surface smoothness and Ge crystallinity, which impacts on reverse leakage current and series resistance. Despite this, the reverse leakage of the diode comprising a layer of intrinsic Ge grown at 300° C. is good and with a reasonably flat surface. This diode may be considered to be the most appropriate for use as a drift layer on SiC for advanced power devices.

Annealing was carried out on the highly-doped diodes. The diode comprising a layer of highly-doped Ge grown at 300° C. and annealed at 450° C. exhibits a much improved forward current, three orders of magnitude higher than that shown in FIG. 5. However, annealing appears to have a detrimental effect on the corresponding device grown at 500° C., reducing the forward current one order of magnitude, though it did reduce the ideality factor to 1.22. These results suggest that annealing transforms the layers into a single nickel germanide layer upon the SiC surface. In both cases, annealing raises the reverse leakage one order of magnitude, most likely due to a reduction in the Ge/SiC effective barrier height.

Capacitance-voltage (C−V) measurements were performed at frequencies ranging from 1 to 500 kHz, and typical (1/C²)−V plots are shown in FIG. 5. The (1/C²)−V curves of an abrupt heterojunction can be analyzed using the expressions found in Journal of Applied Physics, volume 102, page 014505 (2007) ibid. The built-in potential values of 2.0 and 1.5 V are extracted from the diodes having highly-doped Ge layers grown at 300 and 500° C., respectively. The built-in potential of the diodes having intrinsic Ge layers are both 2.2 V. Barrier height values extracted from the I-V plots using a method involving the saturation current yield values ranging from 1.13 eV for the diodes having a highly-doped Ge layer grown at 500° C. to 1.17 eV for the diode having an intrinsic Ge layer grown at 500° C. These are less than the C-V built-in potentials and can be explained by low barrier height zones appearing within the region of higher barriers. Low barrier height regions can appear due to surface defects and may dictate the current flow in a direct regime, such as the I-V measurements. However, during C-V measurements, they are screened by the higher barriers. This effect may be accentuated by the low doping level of the SiC epitaxial layer.

Further devices in accordance with certain embodiments of the present invention will now be described.

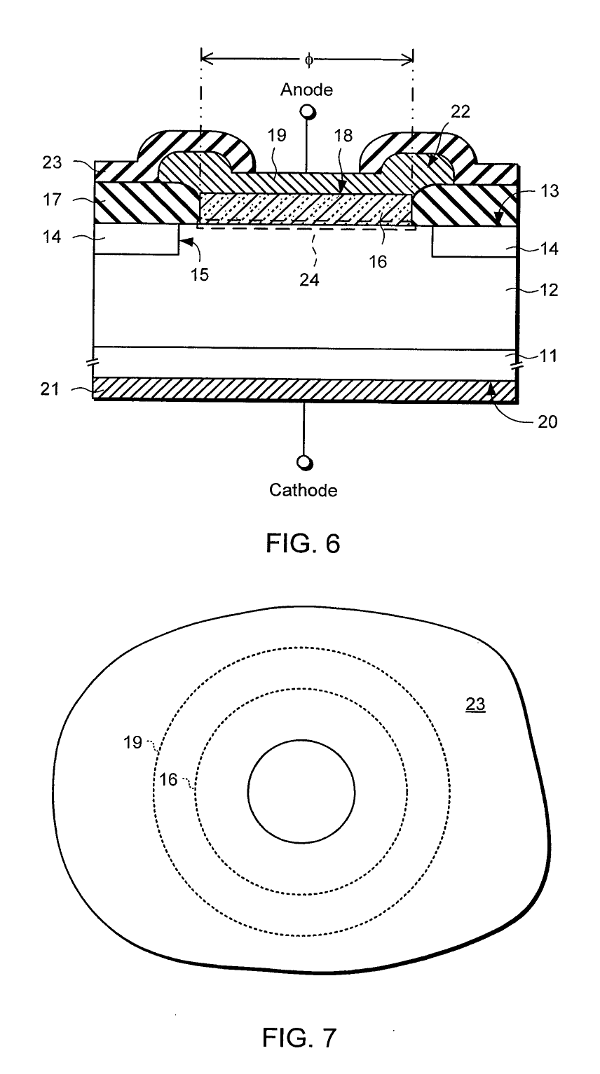

Referring to FIGS. 6 and 7, a heterojunction Schottky barrier diode (hereinafter referred to simply as a “Schottky diode”) is shown.

The Schottky diode comprises a SiC semiconductor substrate 11 and an overlying epitaxial layer 12 of SiC having an upper surface 13. The epitaxial SiC layer 12 has a thickness of about 10 μm, although a thicker layer can be used. The SiC substrate 11 and epitaxial SiC layer 12 are both doped and share the same conductivity type (e.g. n-type). For example, the SiC substrate 11 may be doped with nitrogen (N) with a concentration of about 1×10¹⁸ cm⁻³ and the epitaxial SiC layer 12 can also be doped with nitrogen, but with a concentration of about 1×10¹⁵ cm⁻³. A wafer which is the same as or similar to the wafer 1 (FIG. 1A) described earlier can be used. Other polytypes of SiC can be used, such as 3C—SiC and 6H—SiC.

An annular junction termination extension (JTE) region 14 having an inner perimeter 15 is formed within the epitaxial SiC layer 12 at the surface 13 of the layer 12. The JTE region 14 is doped and has a conductivity type (e.g. p-type) which is different from the epitaxial SiC layer 12. For example, the JTE region 14 may be doped with an acceptor, e.g. aluminum, with a concentration of about 1×10¹⁴ cm⁻³.

A disc-shaped layer 16 (or disc-shaped “pad”) of intrinsic or doped polycrystalline Ge overlies the SiC epitaxial layer 12 on its surface 13 inside the inner perimeter 15 of the JTE region 14. The Ge layer 16 has a thickness of about 300 nm and a diameter, φ, of about 200 μm. In some embodiments, the Ge layer 16 is amorphous. In certain other embodiments, the Ge layer 16 is crystalline. The Ge layer 16 is intrinsic or doped with an impurity to a concentration of up to about 5×10¹⁹ cm⁻³. If doped, the Ge layer 16 can have the same conductivity type at the epitaxial SiC layer 12. For example, the epitaxial SiC and Ge layers 12, 16 can both be n-type.

Outside the vicinity of the Ge layer 16, the surface 13 of the epitaxial SiC layer 12 (including over the JTE region 14) is covered with a first passivation layer 17. The passivation layer 17 comprises silicon dioxide (SiO₂), although other suitable dielectric materials, such as silicon nitride (Si₃N₄) can be used.

On an upper surface 18, a top metallization 19 covers the Ge layer 16 and a portion of the passivation layer 17. The top metallization 19 forms an electrical contact to the Ge layer 16. On a back surface 20 of the substrate 11, a bottom metallization 21 forms a contact to the SiC substrate 11. The metallization layers 19, 21 may comprise a layer of nickel (Ni) or titanium (Ti) having a thickness, for example, of about 300 nm.

The first passivation layer 17 and a periphery 22 of the top metallization 19 are covered by a second passivation layer 23. The second passivation layer 23 comprises polyimide.

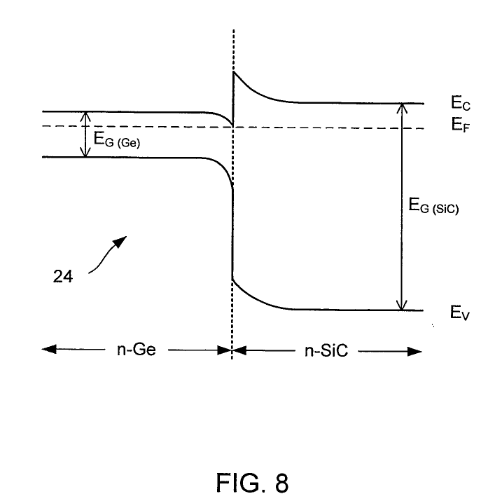

Referring also to FIG. 8, a heterojunction 24, i.e. a junction formed between two dissimilar semiconductors, is formed between the epitaxial the Ge layer 16 and SiC layer 12. If the epitaxial SiC and Ge layers 12, 16 are both n-type, then an isotype heterejunction is formed.

As shown in FIG. 8, the band gap of Ge, which is about 0.66 eV at room temperature, is significantly smaller than that of 4H—SiC, which is about 3.26 eV. The band gap of Ge is also smaller than that of Si, which is about 1.12 eV.

Using a Ge-SiC heterojunction 24 in the Schottky diode can help to reduce the turn-on voltage of the diode. Furthermore, using a Ge-SiC heterojunction 24, the diode can help the diode to turn on more quickly. The diode may also benefit from the higher mobility of Ge.

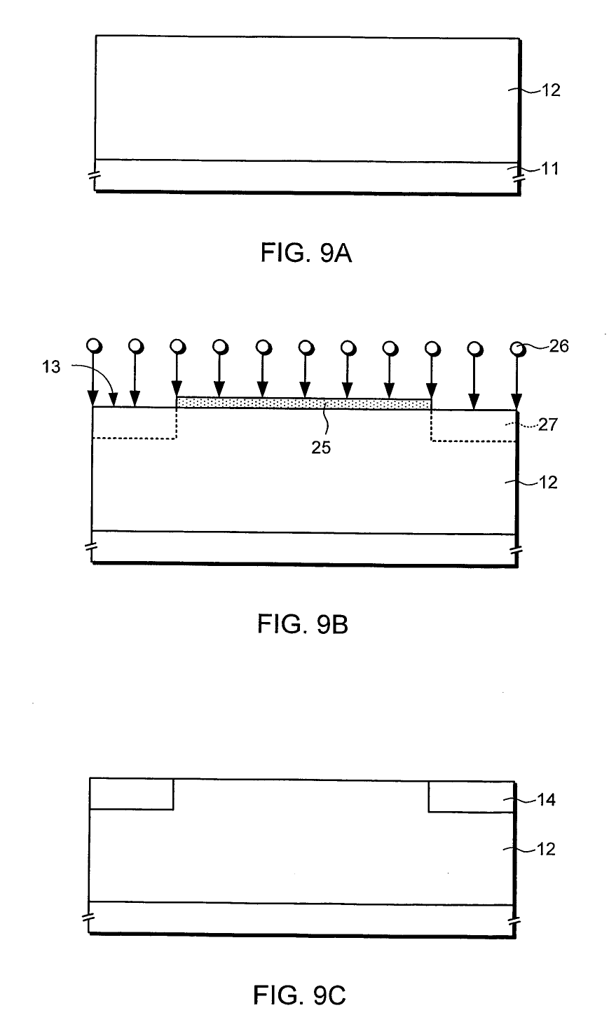

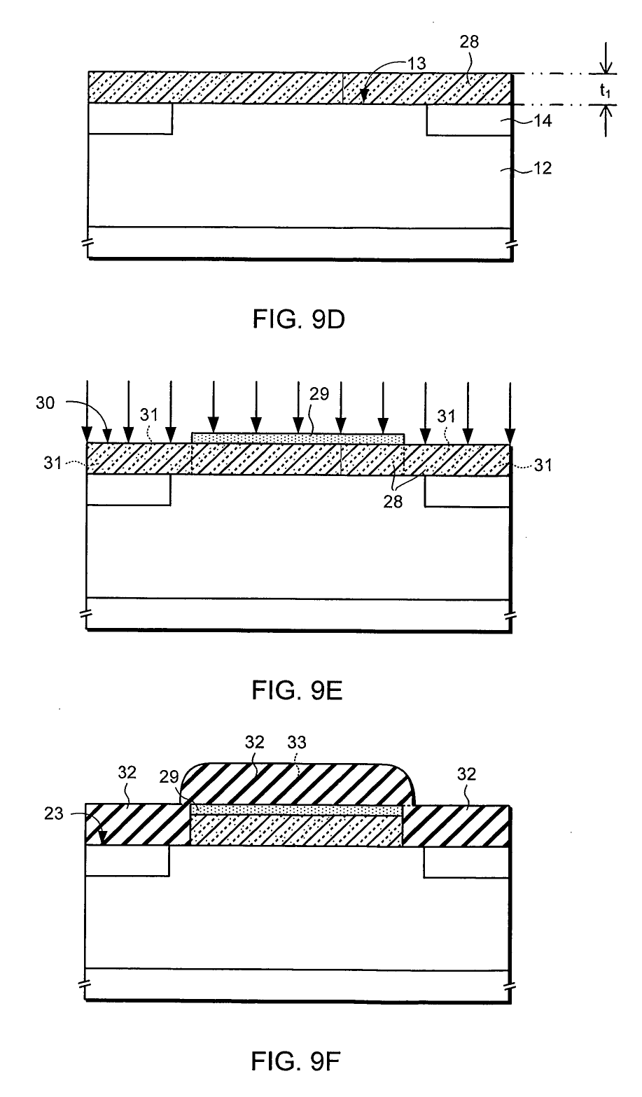

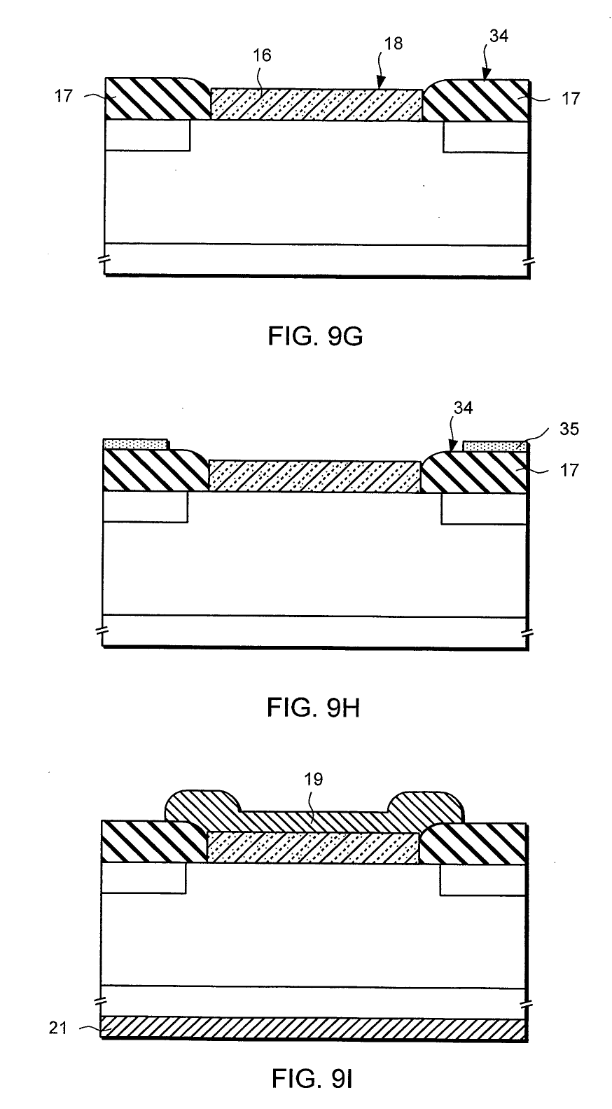

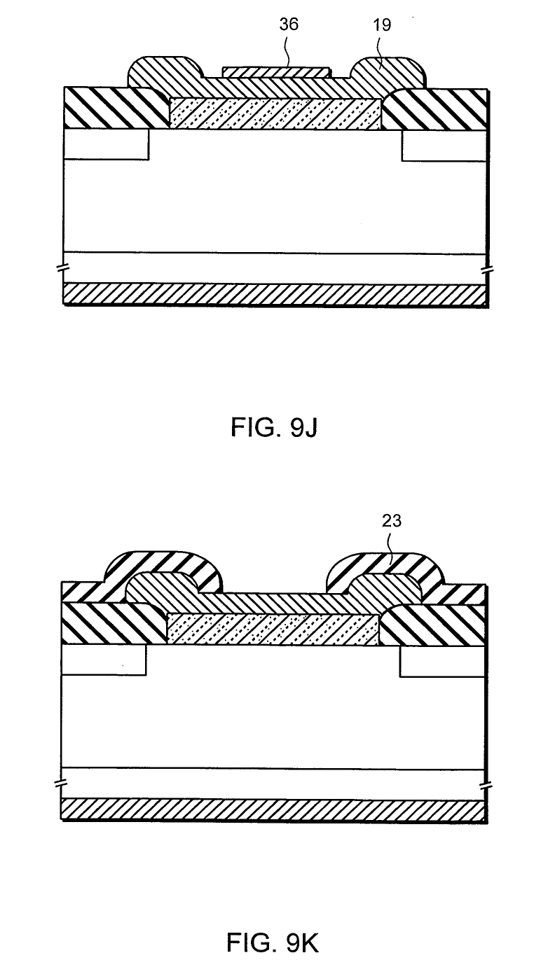

Referring to FIGS. 9A-9K, a method of fabricating the Schottky diode shown in FIGS. 6 and 7 will now be described.

Referring in particular to FIG. 9A, a SiC wafer comprising the SiC semiconductor substrate 11 and the overlying epitaxial layer 12 of SiC is cleaned using the RCA2 process.

Referring now to FIG. 9B, a layer of photoresist (not shown) is deposited and patterned to provide a patterned photoresist layer 25 on the upper surface 13 of the epitaxial layer 12 to mask the intended gate anode area. Aluminum (Al) ions 26 are implanted into unmasked upper regions 27 of the epitaxial layer 12 using multiple exposures, each having a dose of about 1×10¹³ cm⁻².

The photoresist layer 25 is removed. The resulting structure, including JTE region 14, is shown in FIG. 9C.

Referring to FIG. 9D, following an RCA clean, a layer 28 of polycrystalline Ge is grown on the epitaxial SiC surface 13 using MBE at about 500° C. The Ge layer 28 has a thickness, t₁, of about 300 nm.

The Ge layer 28 need not be polycrystalline, but can be crystalline or amorphous. The Ge layer 28 may be deposited using other types of deposition process, such as chemical vapour deposition (CVD), sputtering, e-beam evaporation or wafer bonding

Referring to FIG. 9E, a layer of photoresist (not shown) is applied and patterned to provide a patterned photoresist layer 29 on an upper surface 30 of the Ge layer 28. Unmasked regions 31 of the Ge layer 28 are etched using a reactive ion etch (RIE) using a mixture of carbon tetrafluoride (CF₄) and (about 9%) oxygen (O₂) at about 25 mTorr. Other feed gases can be used, such as sulfur hexafluoride (SF₆).

Referring to FIG. 9F, without removing the mask 29, a layer 32 of SiO₂ is deposited over the uncovered SiC surface 23 and the mask 29 using chemical vapour deposition (CVD). For example, plasma-enhanced CVD (PECVD) can be used using tetra-ethoxy-silane or silane as a precursor.

The mask 29 is removed and unwanted portion 33 of SiO₂ layer (mainly the region overlying the mask 29) is ‘lifted-off’ in a solvent, such as acetone. The resulting structure, including patterned SiO₂ layer 17, is shown in FIG. 9G.

The surface 34 of the sample, including the surface 18 of the Ge layer 19, is cleaned using aqueous ammonia (not shown) and aqueous sulfuric acid (not shown).

Referring to FIG. 9H, a layer of photoresist (not shown) is applied and patterned to provide a patterned photoresist layer 35 on the upper surface 34 on the SiO₂ layer 17.

Referring to FIG. 9I, a layer (not shown) of metallization, in this example either Ni or Ti, is deposited on the front of the device by sputtering or by electron-beam evaporation. Likewise, a layer 21 of metallization is deposited on the back of the device.

The mask 35 is removed and unwanted portions of the top metallization layer are lifted-off in a solvent. The resulting structure, including front metallization layer 19, is shown in FIG. 9I.

Referring to FIG. 9J, a layer of photoresist (not shown) is applied and patterned to provide a patterned photoresist layer 36 on the upper surface of the top metallization 19.

A layer of polyimide (not shown) is applied and is patterned using photolithography. The photoresist developer not only removes unexposed photoresist, but also etches the underlying polyimide.

The resulting structure, including patterned polyimide layer 23, is shown in FIG. 9K.

The structure is annealed at about 300° C.

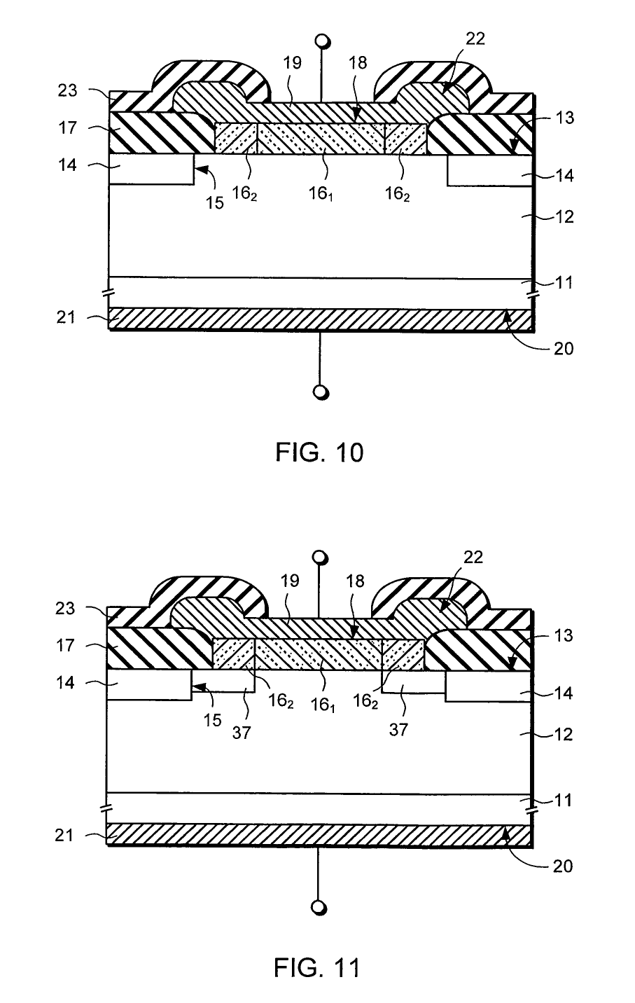

Referring to FIG. 10, a heterojunction junction bipolar Schottky diode is shown.

The junction bipolar Schottky diode is similar to the Schottky diode hereinbefore described. Therefore, the same reference numerals are used to refer to the same features.

The junction bipolar Schottky diode differs from the Schottky diode hereinbefore described in that rather than having a Ge layer which is intrinsic or has the same conductivity type throughout as the underlying epitaxial SiC layer, the junction bipolar Schottky diode includes Ge layer which comprises a central portion 16₁ which is intrinsic or has the same conductivity type as the underlying epitaxial SiC layer and an outer, annular portion 16₂ which has the opposite conductivity type from the underlying epitaxial SiC layer. For example, the central portion 16, may be n-type having a doping concentration of about 1×10¹⁵ cm⁻³ and the outer portion 16₂ may be p-type having a doping concentration of about 1×10¹⁹ cm⁻³.

The junction bipolar Schottky diode can combine the advantages of a Schottky diode and a PiN diode. Thus, the diode can exhibit a low voltage drop across the device in the on-state and fast switching, similar to a Schottky diode, and low leakage in the off-state, similar to a PiN diode.

Referring to FIG. 11, an alternative heterojunction junction bipolar Schottky diode is shown.

The alternative junction bipolar Schottky diode shown in FIG. 11 is similar to the junction bipolar Schottky diode shown in FIG. 10 and so the same reference numerals are used to refer to the same features. However, the alternative junction bipolar Schottky diode includes an additional annular doped region 37 which has the same conductivity type as the overlying outer portion 16₂ of the Ge layer.

The junction bipolar Schottky diodes are fabricated in a similar way to the Schottky diode hereinbefore described. Therefore, a description of the complete manufacturing process will not be repeated here. However, additional processing stages will be described.

Processing of the junction bipolar Schottky diodes proceeds up to and including defining the Ge layer 16 and the SiO₂ layer 17 as shown in FIG. 9G.

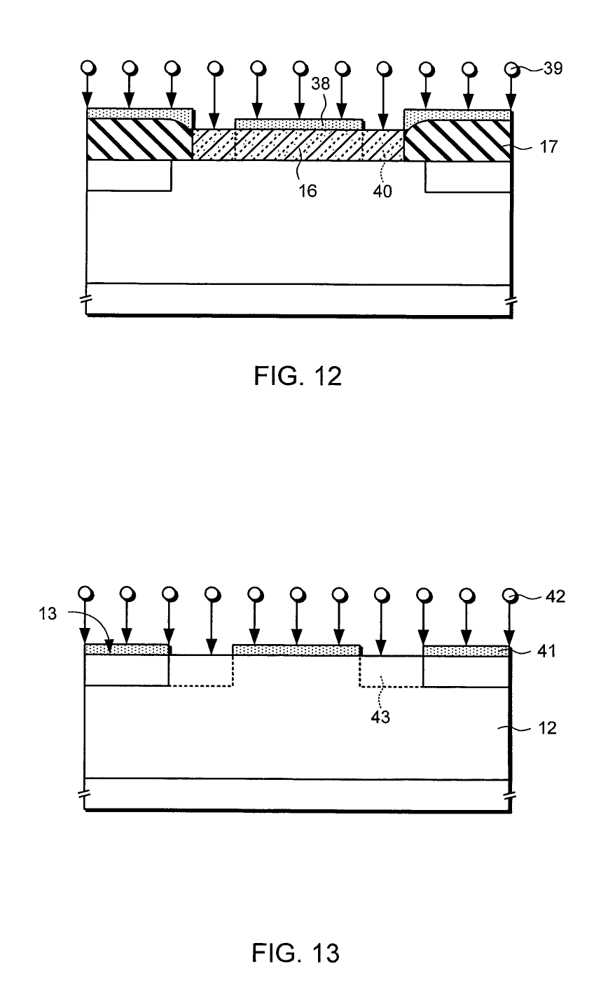

Referring to FIG. 12, to form the doped annular region in the Ge layer 16, a layer of photoresist (not shown) is applied and patterned to provide a patterned photoresist layer 38 on the upper surface 34 of the Ge layer 16 and the SiO₂ layer 17. Aluminum ions 39 are then implanted into unmasked upper regions 40 of the Ge layer 16.

Referring to FIG. 13, to form the annular doped region 37 (FIG. 11) in the SiC epitaxial layer 12, a layer of photoresist (not shown) is applied and patterned to provide a patterned photoresist layer 41 on the upper surface 13 of the epitaxial SiC layer 12. Aluminum ions 42 are then implanted into unmasked upper regions 43 of the epitaxial SiC layer 12.

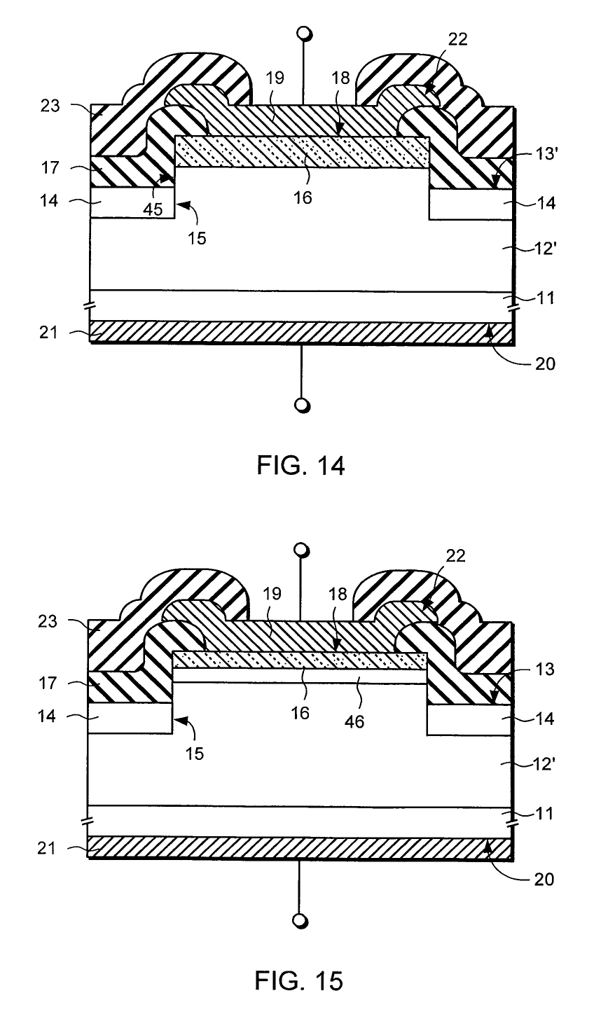

Referring to FIG. 14, a heterojunction PiN diode is shown.

The PiN diode shown in FIG. 14 is similar to Schottky diode shown in FIG. 6, except in three respects.

Firstly, the epitaxial SiC layer is etched to form a patterned epitaxial layer 12′ having a stepped upper surface 13′ including trench sidewalls 45 which defines a mesa region beneath the Ge layer 16.

Secondly, the epitaxial SiC layer has a lower doping concentration, namely a doping concentration of about 1×10¹⁴ cm⁻³. However, the conductivity type of the SiC layer can remain the same, for example, n-type.

Thirdly, the conductivity type of the Ge layer 16 is opposite to the conductivity type of the SiC layer, for example, p-type, and also it is highly doped, for example, having a concentration about 1×10¹⁹ cm⁻³.

Referring to FIG. 15, an alternative heterojunction PiN diode is shown.

The PiN diode shown in FIG. 15 is similar to PiN diode shown in FIG. 14, except a region of the epitaxial layer 12′ includes an implanted region 45 which shares the same conductivity type as the overlying Ge layer 16, but which is opposite to the conductivity type of the rest SiC layer 16.

The PiN diodes are fabricated in a similar way to the Schottky diode hereinbefore described. Therefore, a description of the complete manufacturing process will not be repeated. However, omitted and additional processing stages will be described.

The stage of defining the JTE region 14, as shown in FIGS. 9B and 9C, is not carried out before deposition of the Ge layer 28, as shown in FIG. 9D. Instead, the Ge layer 28 is grown on an unprocessed SiC wafer.

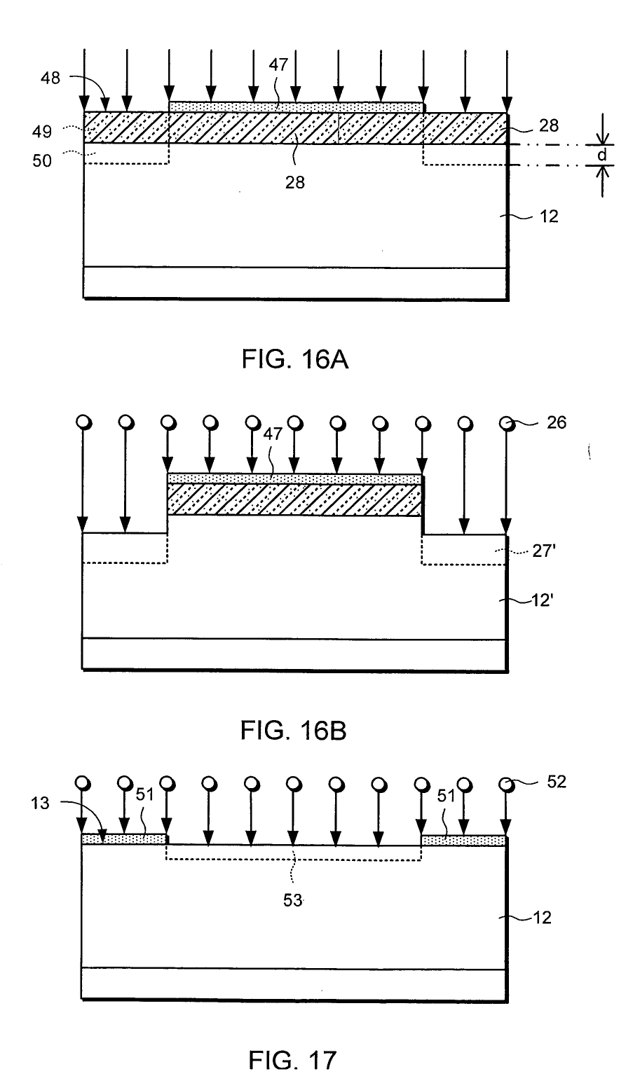

Referring to FIG. 16A, a layer of photoresist (not shown) is applied and patterned to provide a patterned photoresist layer 47 on the upper surface 48 of the unpatterned polycrystalline Ge layer 28. Unmasked regions 49 of the Ge layer 28 are etched using a reactive ion etch (RIE). The etch continues into the epitaxial SiC layer 12 to remove surface portions 50 of the epitaxial SiC layer 12 so as to define a trench. The etch penetrates a depth, d, into the epitaxial SiC layer 12.

Referring to FIG. 16B, without removing the mask 47, aluminum ions 26 are implanted into unmasked upper regions 27′ of the etched epitaxial layer 12′ (i.e. into the bottom of the trench) using multiple exposures, each having a dose of about 1×10¹³ cm⁻².

The mask 47 is removed and the PiN diode is then fabricated using the same steps used to fabricated the Schottky diode, as shown in FIGS. 9F-9K.

To fabricate the alternative PiN diode, an additional fabrication stage is included before the un-patterned polycrystalline Ge layer 28 is deposited.

Referring to FIG. 17, a layer of photoresist (not shown) is applied and patterned to provide a patterned photoresist layer 51 on the upper surface 13 of the un-patterned polycrystalline Ge layer 28. The mask 51 is an inverse of the mask 47 (FIG. 16A) subsequently used for trench formation. Aluminum ions 52 are implanted into unmasked upper regions 53 of the epitaxial layer 12.

The devices hereinbefore described can be used as power rectifiers. However, other types of devices, such as metal-oxide-semiconductor field effect transistors, can employ a Ge/SiC heterojunction, as will now be described in more detail.

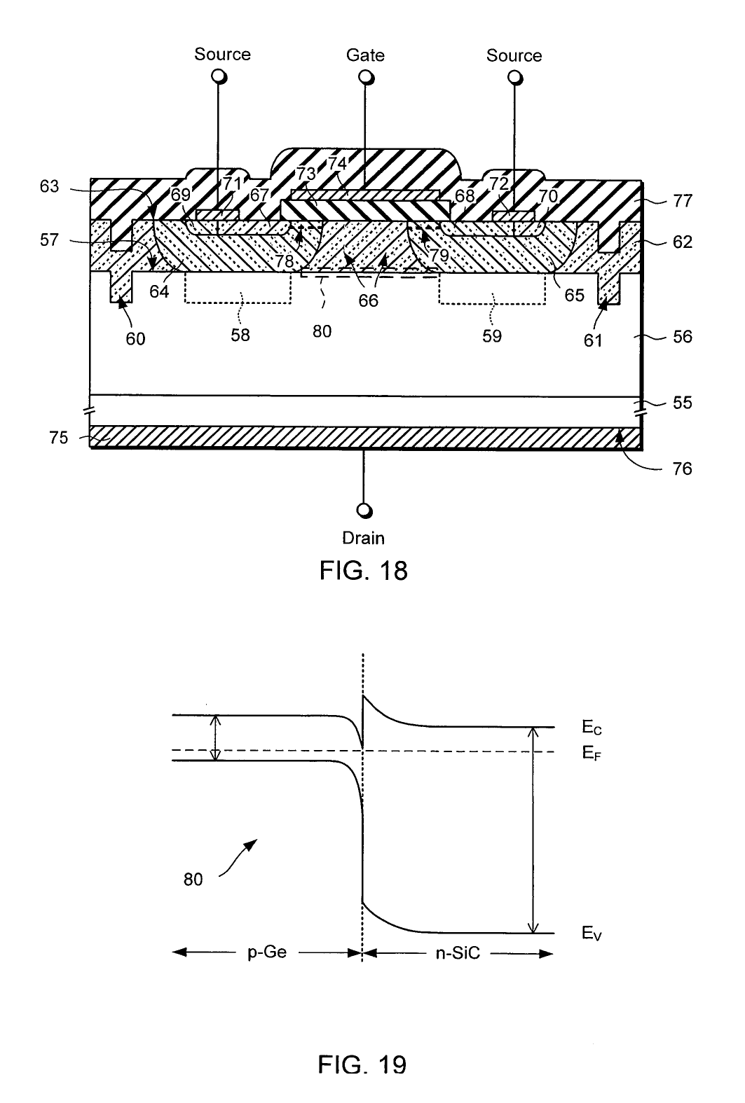

Referring to FIGS. 18 and 19, a heterojunction metal-oxide-semiconductor field effect transistor (MOSFET) is shown. In particular, as shown in FIG. 18, the device is vertical-channel, double-diffusion-type MOSFET or “DMOSFET”. In this case, a p-channel device is described. Herein, the term “MOSFET” is intended to cover FETs in which, for example, a high-k dielectric material which may or may not be an oxide.

The MOSFET comprises a SiC semiconductor substrate 55 and an overlying epitaxial layer 56 of SiC having an upper surface 57. The epitaxial SiC layer 56 has a thickness of about 10 μm, although a thicker layer can be used. The SiC substrate 55 and epitaxial SiC layer 57 are both doped and share the same conductivity type (e.g. n-type). For example, the SiC substrate 55 may be doped with nitrogen (N) with a concentration between about 1×10¹⁷ cm⁻³ and about 1×10¹⁹ cm⁻³ and the epitaxial SiC layer 56 can also be doped with nitrogen, but with a concentration of between about 1×10¹⁴ cm⁻³ and about 1×10¹⁶ cm⁻³. A wafer which is the same as or similar to the wafer 1 (FIG. 1A) described earlier can be used.

If the device is an n-channel device, then first and second laterally spaced, co-planar p-type SiC well regions 58, 59 can be provided in the epitaxial SiC layer 56 at the surface 57 of the layer 56 so as to move the breakdown point towards the SiC layer 56. The well regions 58, 59 may be doped with an acceptor with a concentration of between about 1×10¹⁶ cm⁻³ and about 1×10¹⁸ cm⁻³.

The MOSFET is isolated from adjacent MOSFETs (not shown) and other devices by means of first and second trenches 60, 61 etched into the epitaxial SiC layer 56.

As explained earlier, in this example, the device has a p-type channel. Therefore, a layer 62 of lightly-doped p-type polycrystalline Ge overlies the SiC epitaxial layer 56 and has an upper surface 63. The Ge layer 62 has a thickness of about 1000 nm. In certain embodiments, the Ge layer 62 is crystalline. In some embodiments, the Ge layer 62 is amorphous. The Ge layer 62 is doped with an impurity with a concentration of between about 1×10¹⁶ cm⁻³ and about 1×10¹⁸ cm⁻³.

First and second doped body regions 64, 65 are formed in the Ge layer 62 extending between from the upper surface 57 of the epitaxial SiC layer 56 to the upper surface 63 of the Ge layer 62. The body regions 64, 65 are aligned with the SiC well regions 58, 59, if present. In the case of a p-type channel, the body regions 64, 65 are doped n-type. The body regions 64, 65 may be doped with an impurity with a concentration of between about 1×10¹⁶ cm⁻³ and about 1×10¹⁸ cm⁻³.

As shown in FIG. 18, a portion 66 of the Ge layer 62 lying between the body regions 64, 65 provides a drift region. In this example, the MOSFET is a p-channel device, i.e. the drift region 66 is p-type, and so the body regions 64, 65 are n-type. However, the MOSFET may be an n-channel device and so the body regions 64, 65 may be p-type.

First and second heavily-doped source regions 67, 68 and first and second heavily-doped body contact regions 69, 70 are formed in the first and second body regions 64, 65. Each source region 67, 68 has the same conductivity type as the Ge layer 62. The body contact regions 69, 70 have the same conductivity type as the body regions 64, 65. Thus, in the case of a p-type channel, the source regions 67, 68 are p-type and the body contact regions 69, 70 are n-type.

First and second source electrodes 71, 72 overlie the highly-doped regions 67, 68, 69, 70. As shown in FIG. 18, each electrode 71, 72 spans the source and body contact regions 67, 68, 69, 70.

A gate dielectric layer 73 lies between the source contacts 71, 72. In this example, the gate dielectric comprises silicon dioxide. However, other gate dielectric materials may be used, particularly so-called “high-k” dielectric materials, such as hafnium dioxide, aluminum oxide or zirconium silicate. A gate electrode 74 overlies the gate dielectric 73. A drain electrode 75 is provided on the reverse side 76 of the SiC substrate 55. The electrodes 71, 72, 74, 75 may be formed of nickel or titanium.

The device is protected by a conformal passivation layer 77 overlying the top contacts, 71, 72, 74 and exposed regions of the Ge layer 62.

The device operates as normally-off MOSFET. Thus, in the case of a p-channel device, when no bias is applied to the gate electrode 74, no electrons pass from drain to source. When a bias is applied to the gate electrode 74 which is negative with respect to the source, an inversion layer 78, 79 is formed in each body region 64 under the gate electrode 74 through which electrons can flow from the drift region 66 to the source regions 67, 68.

Referring also to FIG. 18, a heterojunction 80 is formed between the epitaxial the polycrystalline Ge bulk region 66 and SiC epilayer 56. In this example, an anisotype heterojunction is formed.

The MOSFET may benefit from the higher mobility of Ge (compared with Si). Moreover, the surface roughness of the Ge following deposition onto the SiC can be smoother than that of Si deposited on SiC. This may reduce scattering events within the channel region, thus maintaining a higher channel mobility.

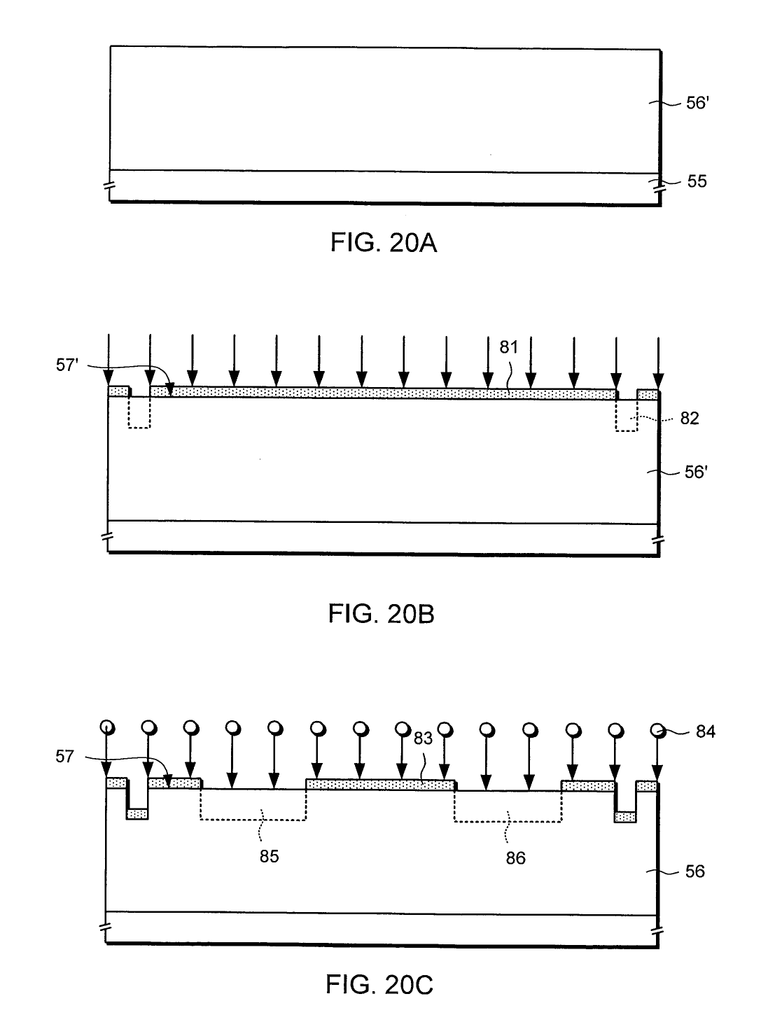

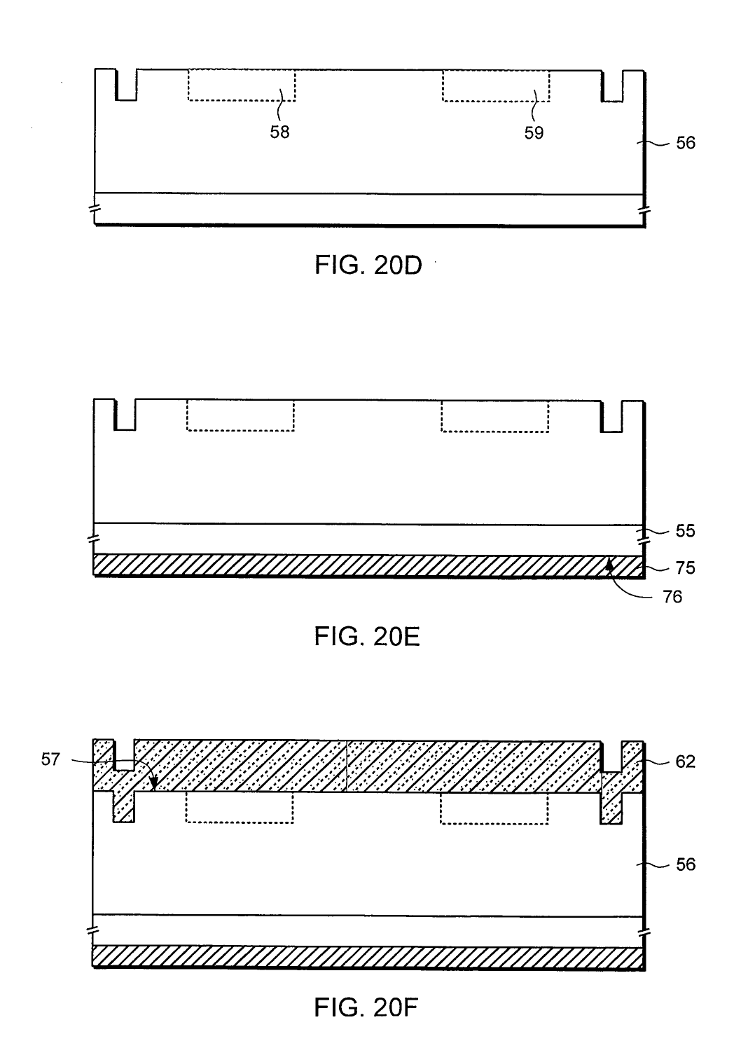

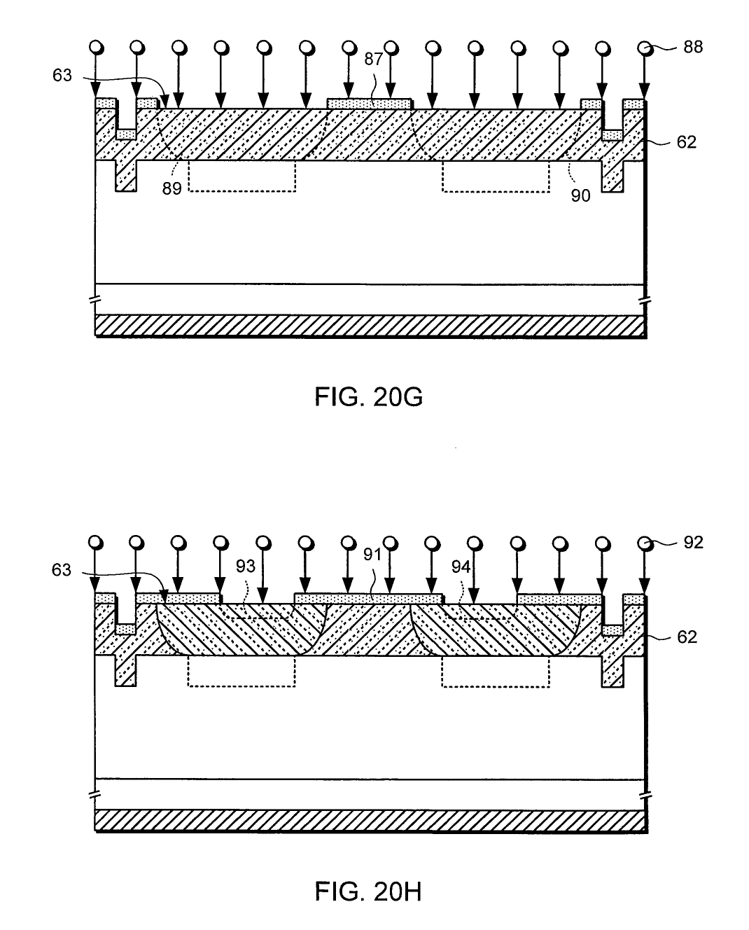

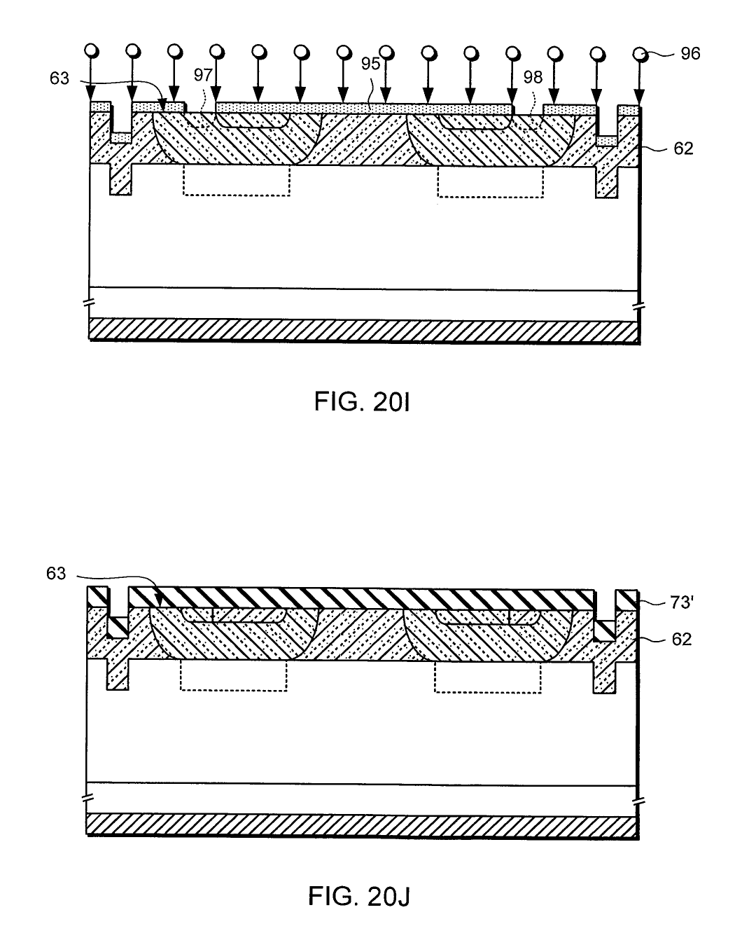

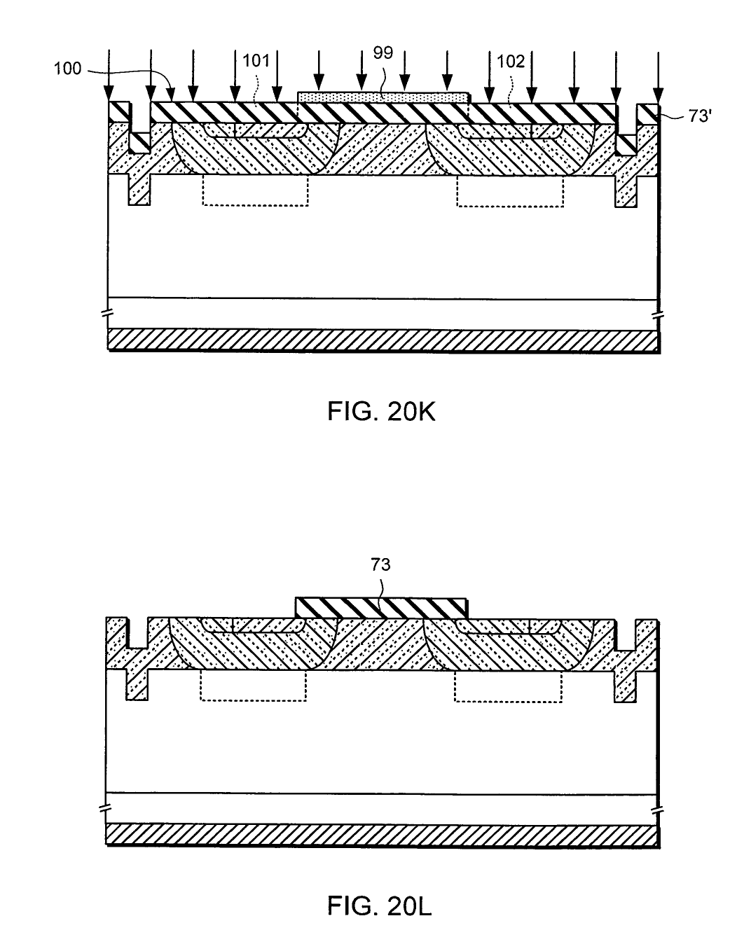

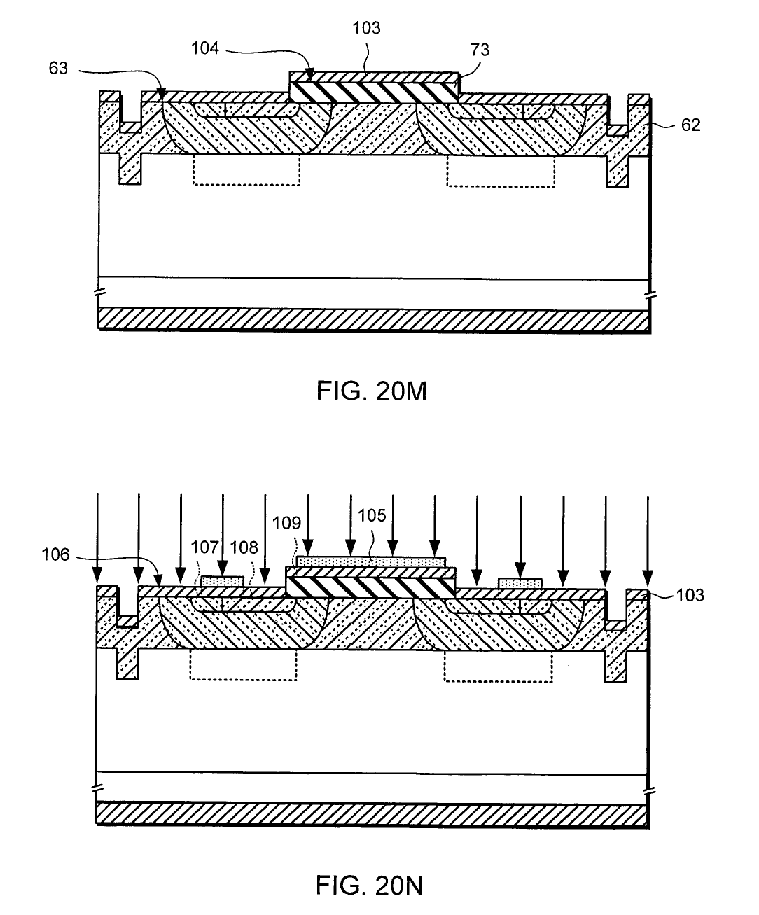

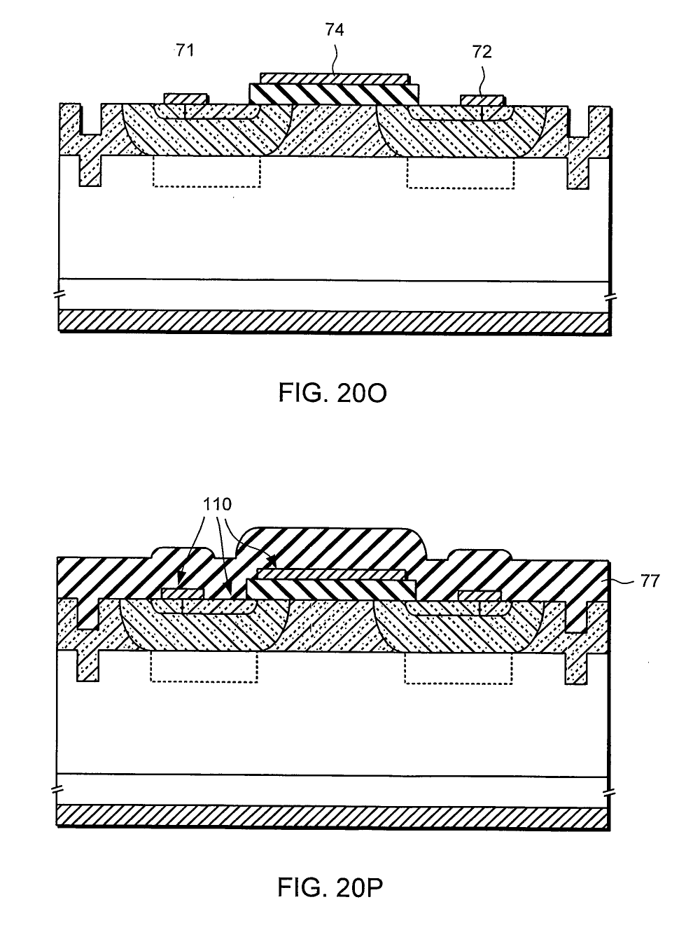

Referring to FIGS. 20A-20P, a method of fabricating the MOSFET shown in FIGS. 18 and 19 will now be described

Referring in particular to FIG. 20A, a SiC wafer comprising the SiC semiconductor substrate 55 and the overlying epitaxial layer 56′ of SiC is cleaned using the RCA2 process.

For an n-channel MOSFET, implanted p-type wells can be defined, as will now be described with reference to FIGS. 20B and 20C. However, for a p-channel MOSFET, the wells are not required and so the stages of defining the wells can be omitted.

Referring to FIG. 20B, a layer of aluminum (not shown) is deposited and patterned using photolithography to provide a patterned mask 81 on the upper surface 57′ of the epitaxial layer 56′. The photodeveloper also serves to etch the aluminum layer (not shown). Photoresist is removed before portions 82 of the epitaxial SiC layer 56′ are etched by a plasma etching process using a mixture of sulfur hexafluoride and oxygen (SF₆/O₂). After the plasma etching process, the mask 81 is removed.

Referring to FIG. 20C, another layer of aluminum (not shown) is deposited and patterned using photolithography to provide a patterned mask 83 on the upper surface 57 of the etched epitaxial layer 56. Al or B ions 84 implanted into unmasked regions 85, 86 of the epitaxial SiC layer 56 using multiple exposures at energies ranging from about 25 to about 320 keV. The mask 83 is removed, the implant is activated using a rapid thermal anneal (RTA) at about 1650° C. in a high-temperature SiC furnace. The resulting structure, including wells 58, 59 implanted into the epitaxial SiC layer 56, is shown in FIG. 20D.

Referring now to FIG. 20E, a back contact 75 is formed by depositing a thin (>100 nm) layer of Ni on the back surface 76 of the SiC substrate 55 and annealing the layer at a temperature of about 900 to 1100° C. An over layer of Al or Ti can then be deposited to facilitate bonding.

The partially-processed wafer is cleaned using the RCA2 process and loaded into an MBE system. The wafer 1 is given a high-temperature to desorb any native oxide (not shown) and any other contaminants (not shown)

Referring to FIG. 20F, a polycrystalline layer 62 of doped Ge (p-type Ge in the case of a p-channel device) is grown at a temperature of about 500° C. over the upper surface 57 of the epitaxial SiC layer 56.

Referring to FIG. 20G, a layer of aluminum (not shown) is deposited and patterned using photolithography to provide a patterned mask 87 on the upper surface 63 of the Ge layer 62. Phosphorous ions 88 are implanted into unmasked regions 89, 90 of the epitaxial Ge layer 62. The mask is removed and the implant is activated by annealing at a temperature of about 400 to 600° C.

Referring to FIG. 20H, a layer of photoresist (not shown) is applied and patterned to provide a patterned mask 91 on the upper surface 63 of the Ge layer 62 to define regions 93, 94 which will form the heavily-doped p-type source regions 67, 68 (FIG. 18). Boron (B) ions 92 are implanted into unmasked regions 93, 94 of the epitaxial Ge layer 62. The resist is removed and the implant is activated by annealing at a temperature of about 400 to 600° C.

Referring to FIG. 20I, another layer of photoresist (not shown) is applied and patterned to provide a patterned mask 95 on the upper surface 63 of the Ge layer 62 to define regions 97, 98 which will form the heavily-doped n-type body contact regions 69, 70 (FIG. 18). Phosphorous ions 96 are implanted into unmasked regions 97, 98 of the epitaxial Ge layer 62. The implant is activated with by annealing at a temperature of about 400 to 600° C.

Referring to FIG. 20J, the surface 63 of the Ge layer 62 is cleaned using aqueous ammonia and aqueous sulfuric acid and the partially processed wafer is loaded into a deposition system (not shown). A layer 73′ of dielectric material, such as SiO₂ or a high-k dielectric, is deposited, for example, using atomic layer deposition (ALD), metal-organic chemical vapour deposition (MOCVD), MBE, d.c. sputtering or e-beam evaporation.

Referring to FIG. 20K, a layer of photoresist (not shown) is applied and patterned to provide a patterned mask 99 on the upper surface 100 of the dielectric layer 73′ to define a region 73 which will form the gate area. Portions 101, 102 of the dielectric layer 73′ are etched using a selective etch, such as diluted hydrofluoric acid. The resulting structure, including gate dielectric 73, is shown in FIG. 20L.

Referring to FIG. 20M, a layer 103 of metal, such as aluminum or copper, is applied to the upper surface 63 of the Ge layer 62 and the upper surface 104 of the gate dielectric 73.

Referring to FIG. 20N, a layer of photoresist (not shown) is applied and patterned to provide a patterned mask 105 on the upper surface 106 of the metal layer 103 to define regions which will form the electrodes 71, 72, 74 (FIG. 18). Portions 107, 108, 109 of the metal layer 103 are etched using a selective etch, such as nitric acid (HNO) for copper or a mixture of nitric acid (HNO₃), phosphoric acid (H₃PO₄) and acetic acid (CH₃COOH) for aluminum. The resulting structure, including electrodes 71, 72, 74, is shown in FIG. 20O.

Finally, referring to FIG. 20P, a passivation layer 77 is grown over the entire surface 100. The passivation layer may be 400 nm of SiO₂, followed by 700 nm of Si₃N₄.

A photoresist mask (not shown) and a selective etch can be used to open vias (not shown) to contact the electrodes.

It will be appreciated that many modifications may be made to the embodiments hereinbefore described without departing from the spirit and scope of the invention. The MOSFET need not be a DMOSFET as described earlier, but any form of power MOSFET. For example, the MOISFET may be a lateral channel MOSFET or another form of vertical-channel MOSFET, such as a VMOSFET or UMOSFET. Herein, the term “MOSFET” is intended to cover FETs in which the dielectric layer comprises a material other than silicon dioxide.

Other forms of transistors can be used, such as insulated gate bipolar transistor (IGBT) and junction-field effect transistor (JFET).

Polycrystalline Ge need not be used. For example, crystalline Ge can be used. Ge need not be deposited using MBE. For example, other suitable deposition processes can be used, such as chemical vapour deposition (CVD), sputtering, e-beam evaporation or wafer bonding.

The thickness of epitaxial SiC layer need not be 10 μm. For example, the epitaxial layer can be thicker or thinner. Moreover, the epitaxial layer can be doped p-type or be intrinsic. The doping concentration of the epitaxial layer need not be about 1.4×10¹⁵ cm⁻³, but can be higher, for example up to 5×10¹⁹ cm⁻³ or more, or lower.

4H—SiC need not be used. For example, 3C—SiC, 6H—SiC or other polytypes of SiC can be used.

Devices need not necessarily be power devices, but can be low-temperature devices (e.g. cooled to cryogenic temperatures, i.e. 77 K and below), high-speed devices and/or sensors.

1. A silicon carbide semiconductor device comprising:
a region of germanium; and
a region of crystalline or polycrystalline silicon carbide;
the germanium region and the silicon carbide region configured to form a germanium/silicon carbide heterojunction.

2. The device of claim 1, wherein the silicon carbide region comprises an epitaxial layer of silicon carbide.

3. The device of claim 1, wherein the silicon carbide region comprises a layer having a thickness of at least 1 μM.

4. The device of claim 1, wherein silicon carbide region is doped.

5. The device of claim 3, wherein the silicon carbide region is n-type.

6. The device of claim 1, wherein the germanium region is crystalline.

7. The device of claim 1, wherein the germanium region is polycrystalline.

8. The device of claim 1, wherein the germanium region is amorphous.

9. The device of claim 1, wherein the germanium region comprises an epitaxial layer of germanium.

10. The device of claim 1, wherein the germanium region comprises a layer having a thickness of at least one monolayer.

11. The device of claim 1, further comprising:
first and second electrode,
the first and second electrodes, the silicon carbide region and germanium region configured such that, in response to a bias applied between the first and second electrode, a current flows through the germanium/silicon carbide heterojunction.

12. The device of claim 1, which is a rectifier.

13. The device of claim 1, wherein the device is a transistor.

14. A silicon carbide semiconductor device comprising:
a crystalline substrate of silicon carbide;
a layer of epitaxial silicon carbide overlying the silicon carbide substrate; and
a layer of crystalline or polycrystalline germanium overlying the epitaxial silicon carbide layer, wherein a heterojunction is formed at an interface between the germanium layer and the epitaxial silicon carbide layer.

15. The device according to claim 14, wherein the epitaxial silicon carbide layer is n-type and the germanium layer is p-type.

16. The device of claim 14, wherein the germanium layer is intrinsic or doped to a concentration up to about 1×10¹⁵ cm⁻³.

17. A method comprising:
providing a region of crystalline or polycrystalline silicon carbide; and
providing a region of germanium;
the germanium region and the silicon carbide region configured to form a germanium/silicon carbide heterojunction.

18. The method according to claim 17, wherein providing the germanium region comprises depositing a layer of germanium on the silicon carbide region.

19. The method according to claim 18, wherein the germanium layer is deposited at a temperature of between about 200° C. and 600° C.

20. The method according to claim 17, wherein the germanium layer has a thickness of between one monolayer and about 1000 nm.
